(19) United States
(12) Patent Application Publication
(10) Pub. No.: US 2023/0074806 A1
(43) Pub. Date: Mar. 9, 2023

(54) METHODS AND SYSTEMS FOR AUTOMATIC WAVEFORM ANALYSIS

(71) Applicant: Yangtze Memory Technologies Co., Ltd., Wuhan (CN)

(72) Inventors: Liqiang NI, Wuhan (CN); Peng SUN, Wuhan (CN); Weilan ZHAO, Wuhan (CN); Xinyue ZHANG, Wuhan (CN)

(73) Assignee: Yangtze Memory Technologies Co., Ltd., Wuhan (CN)

(21) Appl. No.: 18/046,560

(22) Filed: Oct. 14, 2022

Related U.S. Application Data
(63) Continuation of application No. PCT/CN2021/116438, filed on Sep. 3, 2021.

(51) Int. Cl. G01R 31/28; G01R 31/317; G01R 31/3183

(52) U.S. Cl. CPC G01R 31/2813; G01R 31/31727; G01R 31/318357

(57) ABSTRACT

The present disclosure describes a method for analyzing signal waveforms produced by integrated circuits. The method includes determining characteristic points of a control signal, and each characteristic point includes a corresponding time value and represents an edge change of the control signal. The method also includes determining sets of data sampling points. Each set of data sampling points is located between adjacent characteristic points of the characteristic points. The method further includes obtaining data values of a signal waveform, and a data value of the signal waveform is obtained at a data sampling point of the sets of data sampling points. The method further includes obtaining data values of a reference waveform, and a data value of the reference waveform is obtained at the data sampling point and determining a difference between the data value of the signal waveform and the data value of the reference waveform.

### CROSS-REFERENCE TO RELATED APPLICATIONS

This application is a continuation application of PCT Application No. PCT/CN2021/116438, filed on Sep. 3, 2021, entitled “Methods and Systems for Automatic Waveform Analysis,” which is incorporated herein by reference in its entirety.

### TECHNICAL FIELD

The present disclosure generally relates to methods and systems for analyzing integrated circuits.

### BACKGROUND

With advances in semiconductor technology, there has been increasing demand for higher storage capacity, faster processing systems, higher performance, and lower costs. To meet these demands, the semiconductor industry continues to scale down the dimensions of semiconductor devices. Circuit analysis is performed on the circuit design of semiconductor devices to ensure that the integrated circuits meet a pre-determined specification. An example of circuit analysis is simulating circuit operation conditions and analyzing the resulting digital signals. As circuits become more complicated and larger in scale, increased amount of signal data is collected from the digital signals. There is a need to quickly and accurately analyze the signal data to obtain necessary information and timely detect any circuit abnormalities.

### BRIEF SUMMARY

Embodiments of methods for simulating power circuits and systems for performing the same are described in the present disclosure.

In some embodiments, a method for analyzing signal waveforms produced by an integrated circuit includes determining characteristic points of a control signal. Each characteristic point includes a corresponding time value and represents an edge change of the control signal. The method also includes determining sets of data sampling points. Each set of data sampling points is located between adjacent characteristic points of the characteristic points. The method further includes obtaining data values of a signal waveform, and a data value of the signal waveform is obtained at a data sampling point of the sets of data sampling points. The method further includes obtaining data values of a reference waveform, and a data value of the reference waveform is obtained at the data sampling point. The method also includes determining a difference between the data value of the signal waveform and the data value of the reference waveform.

In some embodiments, a method for analyzing signal waveforms produced by an integrated circuit includes determining characteristic points of a control signal. Each characteristic point includes a corresponding time value and represents an edge change of the control signal. The method also includes determining time durations, where each time duration is between adjacent time values of respective adjacent characteristic points of the characteristic points. The method also includes obtaining a first plurality of data values of a signal waveform in a first time duration and obtaining a first plurality of data values of a reference waveform in the first time duration. The method further includes determining, using a first analysis method, a first difference between the first plurality of data values of the signal waveform and the first plurality of data values of the reference waveform. The method further includes obtaining a second plurality of data values of the signal waveform in a second time duration and obtaining a second plurality of data values of the reference waveform in the second time duration. The method further includes determining, using a second analysis method different from the first analysis method, a second difference between the second plurality of data values of the signal waveform and the second plurality of data values of the reference waveform. The method further includes comparing the first or second difference with a threshold tolerance value.

In some embodiments, a non-transitory computer-readable medium containing computer-executable program for, when being executed by a processor, implementing a method for analyzing signal waveforms produced by an integrated circuit, including determining characteristic points of a control signal. Each characteristic point includes a corresponding time value and represents an edge change of the control signal. The method also includes determining sets of data sampling points. Each set of data sampling points is located between adjacent characteristic points of the characteristic points. The method further includes obtaining data values of a signal waveform, and a data value of the signal waveform is obtained at a data sampling point of the sets of data sampling points. The method further includes obtaining data values of a reference waveform, and a data value of the reference waveform is obtained at the data sampling point. The method also includes determining a difference between the data value of the signal waveform and the data value of the reference waveform.

In some embodiments, a waveform analyzing system includes a first processor and a first memory having a first set of computer program codes stored thereon, wherein the first processor is configured to execute the first set of computer program codes in the first memory to (i) determine a plurality of characteristic points of a control signal, wherein each characteristic point comprises a corresponding time value and represents an edge change of the control signal; and (ii) determine a plurality of time durations, wherein each time duration is between adjacent time values of respective adjacent characteristic points of the plurality of characteristic points. The wave analyzing system also includes a second processor and a second memory having a second set of computer program codes stored thereon, wherein the second processor is configured to execute the second set of computer program codes in the second memory to (i) obtain a first plurality of data values of a signal waveform in a first time duration; and (ii) obtain a second plurality of data values of the signal waveform in a second time duration. The wave analyzing system also includes a third processor and a third memory having a third set of computer program codes stored thereon, wherein the third processor is configured to execute the third set of computer program codes in the third memory to (i) obtain a first plurality of data values of a reference waveform in the first time duration; and (ii) obtain a second plurality of data values of the reference waveform in the second time duration. The wave analyzing system also includes a fourth processor and a fourth memory having a fourth set of computer program codes stored thereon, wherein the fourth processor is configured to execute the fourth set of computer program codes in the fourth memory to (i) determine, using a first analysis method, a first difference between the first plurality of data values of the signal waveform and the first plurality of data values of the reference waveform; (ii) determine, using a second analysis method different from the first analysis method, a second difference between the second plurality of data values of the signal waveform and the second plurality of data values of the reference waveform; (iii) comparing the first or second difference with a threshold tolerance value; and (iv) in response to the first or second difference being greater than the threshold tolerance value, adjusting at least one circuit parameter of the integrated circuit.

### BRIEF DESCRIPTION OF THE DRAWINGS

The accompanying drawings, which are incorporated herein and form a part of the specification, illustrate embodiments of the present disclosure and, together with the description, further serve to explain the principles of the present disclosure and to enable a person skilled in the pertinent art to make and use the present disclosure.

FIG. 1A illustrates an exemplary waveform analyzing system, in accordance with some embodiments.

FIG. 1B illustrates a block diagram of an exemplary computer system implementing a waveform analyzing system, in accordance with some embodiments.

FIG. 2 is a schematic diagram illustrating control signals and exemplary signal waveforms, in accordance with some embodiments.

FIG. 3 is an exemplary method for analyzing signal waveforms, in accordance with some embodiments.

FIG. 4 is a schematic diagram illustrating control signals and exemplary signal waveforms, in accordance with some embodiments.

The features and advantages of the present invention will become more apparent from the detailed description set forth below when taken in conjunction with the drawings, in which like reference characters identify corresponding elements throughout. In the drawings, like reference numbers generally indicate identical, functionally similar, and/or structurally similar elements. The drawing in which an element first appears is indicated by the leftmost digit(s) in the corresponding reference number.

Embodiments of the present disclosure will be described with reference to the accompanying drawings.

### DETAILED DESCRIPTION

Although specific configurations and arrangements are discussed, it should be understood that this is done for illustrative purposes only. A person skilled in the pertinent art will recognize that other configurations and arrangements can be used without departing from the spirit and scope of the present disclosure. It will be apparent to a person skilled in the pertinent art that the present disclosure can also be employed in a variety of other applications.

It is noted that references in the specification to “one embodiment,” “an embodiment,” “an example embodiment,” “some embodiments,” etc., indicate that the embodiment described can include a particular feature, structure, or characteristic, but every embodiment can not necessarily include the particular feature, structure, or characteristic. Moreover, such phrases do not necessarily refer to the same embodiment. Further, when a particular feature, structure or characteristic is described in connection with an embodiment, it would be within the knowledge of a person skilled in the pertinent art to affect such feature, structure or characteristic in connection with other embodiments whether or not explicitly described.

In general, terminology can be understood at least in part from usage in context. For example, the term “one or more” as used herein, depending at least in part upon context, can be used to describe any feature, structure, or characteristic in a singular sense or can be used to describe combinations of features, structures or characteristics in a plural sense. Similarly, terms, such as “a,” “an,” or “the,” again, can be understood to convey a singular usage or to convey a plural usage, depending at least in part upon context. In addition, the term “based on” can be understood as not necessarily intended to convey an exclusive set of factors and may, instead, allow for existence of additional factors not necessarily expressly described, again, depending at least in part on context.

Circuit analysis is performed on the integrated circuit design of semiconductor devices to ensure that the integrated circuits being designed meet a pre-determined specification. An example of circuit analysis is simulating circuit operation conditions and analyzing the resulting digital signals. As circuits become more complicated and larger in scale, increased amount of signal data is collected from the digital signals. Methods of analyzing waveforms such as pattern matching are developed to analyze signal waveforms. Pattern matching is a technique that searches for and extracts a portion of a signal waveform within a specific time duration and performs logic operations to compare it to a portion of a reference waveform within the same specific time duration. However, when a delay in signal response occurs that may result in a shift in the entire signal waveform, such techniques can lead to false reports of error even when the signal response delay is within tolerance and the signal waveform should have been as an acceptable signal waveform. Therefore, there is a need to quickly and accurately analyze the signal data to obtain necessary information and timely detect any circuit abnormalities.

Various embodiments in the present disclosure describe methods and systems for analyzing signal waveforms in an integrated circuit. A waveform analyzing system can be configured to receive signal waveforms and analyze the received signal waveforms with respect to one or more reference waveforms. The methods described in the present disclosure includes determining characteristic points of a control signal and sampling data values of signal waveforms and reference waveforms using a data sampling frequency. The data sampling frequency can be provided by a user and can be dependent upon the characteristic points. The data sampling frequency can be different between different time durations that abut adjacent characteristic points. The waveform analyzing system can be configured to measure the sampled signal data from different time durations using different methods. In some embodiments, data is sampled from a mid-point of the time duration. In some embodiments, an average value of the signal waveform is determined for a specific time duration and compared to an average value of a reference waveform within the same specific time duration. In some embodiments, the waveform analyzing system is configured to receive multiple signal waveforms and use different analysis methods to determine if one or more signal waveforms meet a predetermined criteria.

The methods and system of waveform analysis in the present disclosure can use different analysis methods to automatically analyze signal values within time durations of waveforms. Benefits of the methods and system described in the present disclosure can include, but are not limited to, reduced false error reports, adjustable tolerance threshold of waveform analysis, improved and controllable waveform analysis efficiency, among other benefits.

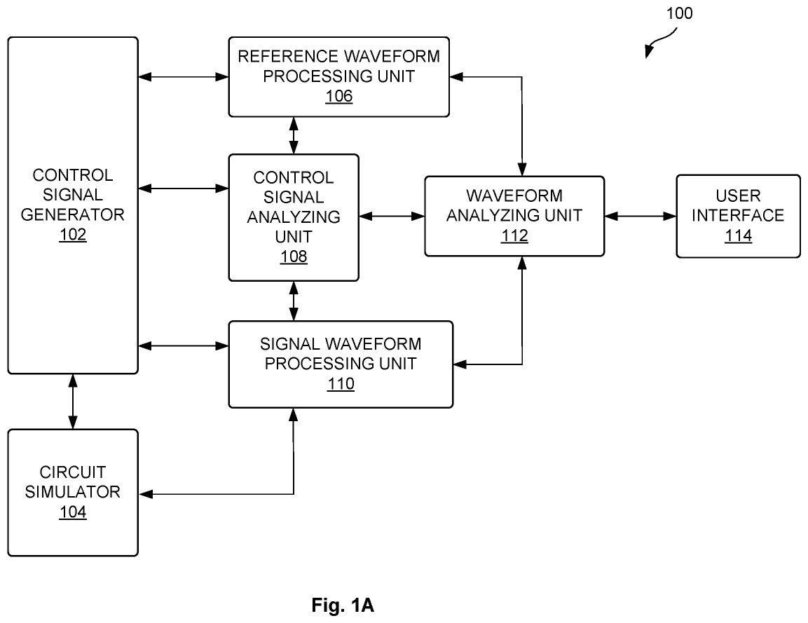

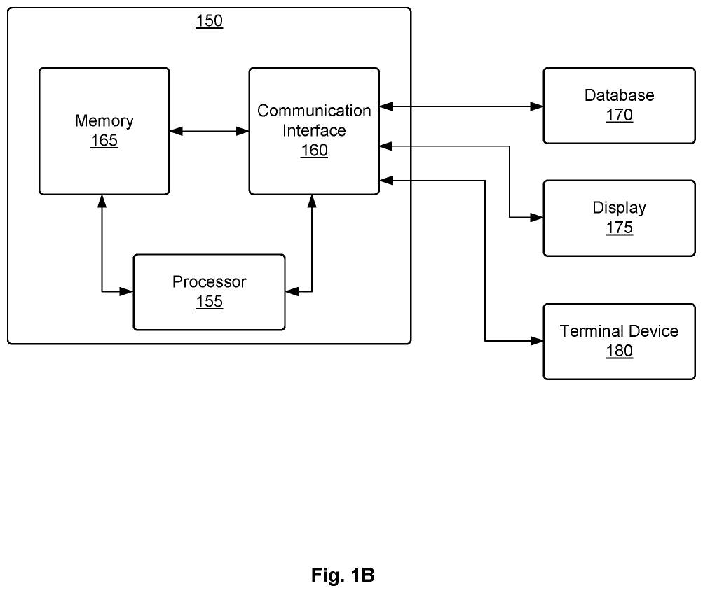

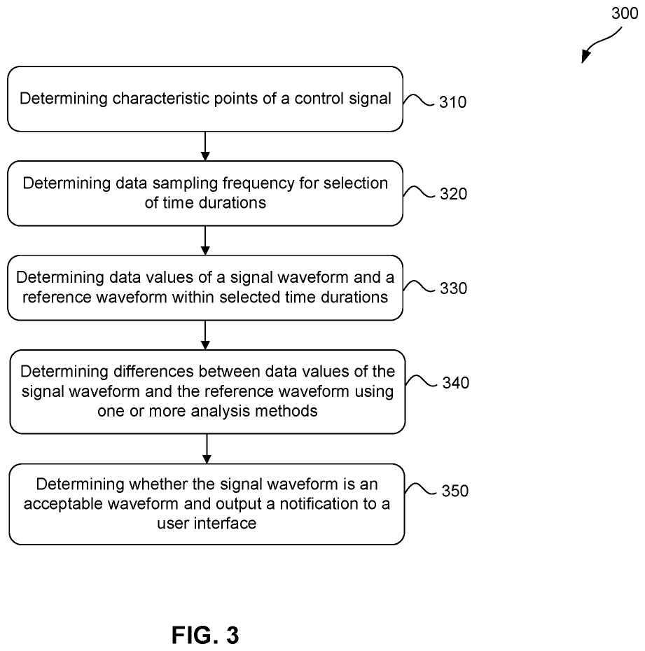

FIG. 1A illustrates a schematic view of an exemplary waveform analyzing system 100, according to some embodiments of the present disclosure. Waveform analyzing system 100 can include a control signal generator 102, an circuit simulator 104, a reference waveform processing unit 106, a control signal analyzing unit 108, a signal waveform processing unit 110, a waveform analyzing unit 112, and a user interface 114. Other components can be included in waveform analyzing system 100 and are omitted from FIG. 1A for simplicity. The circuit components illustrated in FIG. 1A can be formed using suitable computer modules including, but not limited to, processors, power supply modules, sensors, memory storages, input and display devices, I/O modules, and the like. Waveform analyzing system 100 can include any appropriate type of general-purpose or special-purpose microprocessor, digital signal processor, or microcontroller. Waveform analyzing system 100 can be configured as a separate processor module dedicated to performing one or more specific operations. Alternatively, waveform analyzing system 100 be configured as a shared processor module for performing other operations unrelated to the one or more specific operations disclosed herein. Each of control signal generator 102, circuit simulator 104, reference waveform processing unit 106, control signal analyzing unit 108, signal waveform processing unit 110, waveform analyzing unit 112, and a user interface 114 can include one or more processors and memory storages having a set of computer program codes stored thereon. The processors are configured to execute the set of computer program codes in the memories to perform operations such as operations 310-350 described in FIG. 3.

Control signal generator 102 is configured to provide at least a control signal for the operation of one or more integrated circuit components of integrated circuits. In some embodiments, the integrated circuit can be a virtual integrated circuit simulated by a circuit simulator. In some embodiments, virtual integrated circuits can include integrated circuit designs. In some embodiments, control signal generator 102 can be configured to generate a clock signal and a control signal. Clock signals generated for electronic devices, for example, memory array or memory controllers, can be synchronized for all components of the integrated circuit or have controlled phase relationships relative to each component of the integrated circuit. Control signal generator 102 is operative for generating control signals for the operation of integrated circuits, such as memory circuits. For example, control signal generator 102 can produce control signals for controlling the readout and storing of data in three-dimensional NAND memory arrays. In some embodiments, the control signals may include signals, such as clocks, program, read and erase signals, that may be delivered to, for example, column and row select units of three-dimensional NAND memory arrays for managing the timing of the data read and store operations. In some embodiments, control signals can have voltage levels that are time dependent (e.g., changes based on time). Control signal generator 102 is configured to provide clock signals and/or control signals to components of waveform analyzing system 100, such as circuit simulator 104, reference waveform processing unit 106, control signal analyzing unit 108, signal waveform processing unit 110, waveform analyzing unit 112, user interface 114, and/or any other suitable system components.

Circuit simulator 104 is configured to replicate behavior of an actual integrated circuit by using mathematical models. Circuit simulator 104 is configured to perform a series of simulation operations on one or more circuit components, such as circuit components of a three-dimensional NAND memory device, including but not limited to, page buffers, wordline drivers, data processing circuits, memory arrays, peripheral circuits, and the like. Circuit simulator 104 can acquire standard cell information of the aforementioned circuit components and perform circuit-level simulations to produce a simulation result to be received by signal waveform processing unit 110. In some embodiments, circuit simulator 104 is configured to use any suitable tools to generate timing reports, perform timing preserved optimization, and/or perform timing centric routing. Circuit simulator 104 can be configured to output signal data in the form of time-dependent waveforms to be received and processed by waveform analyzing unit 112. In some embodiments, circuit simulator 104 can be an analog or digital electronic circuit simulator, including but not limited to, a simulation program with integrated circuit emphasis (SPICE). The circuit simulator 104 can be a FastSPICE tool such as Spectre XPS, FineSim-Pro, or CustomSim, commercially available by Synopsis Inc., of Mountain View, Calif.

Reference waveform processing unit 106 generates or stores a reference waveform used as a reference for comparing subsequently simulated signal waveforms. In some embodiments, reference waveform can be a standard waveform developed for a certain type of integrated circuit. In some embodiments, reference waveform can be a previously generated signal waveform that is used as a basis for comparison. Subsequently generated signal waveforms can be compared with the reference waveform to provide information for simulation analysis. Reference waveform process unit 106 can also be configured to receive control signals and clock signals from control signal generator 102. In some embodiments, the output of reference waveform processing unit can be a time-dependent signal waveform.

Control signal analyzing unit 108 can be configured to receive control signals from control signal generator 102 and analyze the received control signals. For example, control signal analyzing unit 108 can be configured to identify characteristic points of the received control signal. In some embodiments, characteristic points of a signal represents a change in value of the control signal and the corresponding time of such changes. Therefore, the voltage value of the control signal waveform between two adjacent characteristic points remains substantially constant. For simplicity, the lapsed time between two adjacent characteristic points is referred to a time duration of the control signal waveform. Control signal analyzing unit 108 is configured to detect a rising edge or a falling edge of a control signal waveform by detecting a change in the voltage value of the control signal waveform, and proceed to record the corresponding time of such changes.

Signal waveform processing unit 110 is configured to receive signal waveforms from circuit simulator 104 and obtain signal values of the received signal waveforms. For example, signal waveform processing unit 110 is configured to sample signal waveforms by a pre-determined sampling frequency and obtain signal values of the signal waveforms. Signal waveform processing unit 110 can be configured to sample signal values within specified time durations, such as time durations between adjacent characteristic points. Signal waveform processing unit 110 can send the obtained signal values and corresponding time values to waveform analyzing unit 112 for further processing.

Waveform analyzing unit 112 receives and processes information related to reference waveforms, control signals, and signal waveforms. Waveform analyzing unit 112 can be any appropriate type of general-purpose or special-purpose microprocessor, digital signal processor, or microcontroller. Waveform analyzing unit 112 can operate based on a set of instructions stored in a memory storage within waveform analyzing unit 112 or any other suitable medium. The instructions can be in the form of a scripting language, such as a UNIX c-shell language, a bash-shell language, Python, a Command Line Interface (CLI) language, any suitable scripting language, and/or combinations thereof. In some embodiments, the scripting language is configured to be operated under a Linux platform or any other suitable platforms.

Waveform analyzing unit 112 can also be configured to send instructions to reference waveform processing unit 106 and signal waveform processing unit 110. For example, waveform analyzing unit 112 is configured to send a pre-determined sampling frequency to signal waveform processing unit 110 such that the latter can obtain signal values of signal waveforms according to the sampling frequency. In some embodiments, the sampling frequency is provided for a selection of time durations for the signal waveforms. For example, a sampling frequency can be provided for a first time duration and another sampling frequency can be provided for a second time duration. In some embodiments, the sampling frequencies can be different for two or more signal waveforms.

Waveform analyzing unit 112 is configured to receive and process data received from signal waveform processing unit 110. Waveform analyzing unit 112 can use one or more suitable analysis methods, such as peak analysis, mid-point analysis, average value analysis, any suitable analysis method, and/or combinations thereof. In a peak analysis method, waveform analyzing unit 112 can be configured to identify highest and lowest data values in the received signal values and determine the differences between the aforementioned data values. The peak analysis method can also be referred to as a peak-to-peak analysis method. In some embodiments, waveform analyzing unit 112 can also record the time value of the aforementioned data values. In some embodiments, waveform analyzing unit 112 is configured to obtain signal values measured at a mid-point of one or more time durations, referred to as a mid-point analysis method. For example, waveform analyzing unit 112 obtains a data value of signal waveform at time value 50 μs within a time duration of about 100 μs. In some embodiments, waveform analyzing unit 112 can also determine an average value of signal values within one or more time durations. For example, waveform analyzing unit 112 can calculate an average value of all data values obtained within one or more time durations.

Waveform analyzing unit 112 is further configured to determine if data values of one or more signal waveforms exceed a threshold tolerance value and proceed to record an error signal. Alternatively, if the data value is below a threshold tolerance value, waveform analyzing unit 112 is configured to record an acceptable signal. Waveform analyzing unit 112 can perform the analysis on a portion of or an entire series of received signal waveform and record the total amount of error signals and acceptable signals. Waveform analyzing unit 112 can further determine a ratio of the number of acceptable signals over the number of error signals. If the ratio is less than a predetermined ratio value, waveform analyzing unit 112 sends an alert to user interface 114. Alternatively, if the ratio is greater than a predetermined ratio value, waveform analyzing unit 112 sends a message to user interface 114 indicating that the signal waveform meets the pre-determined criteria.

User interface 114 is configured to receive and display information from waveform analyzing unit 112 as well we receiving user input to adjust any suitable settings of waveform analyzing unit 112. In some embodiments, user interface 114 can include a graphical display for displaying information and a communication interface for interacting with a user. A user can enter information such as threshold tolerance values, ratio values, sampling frequencies, among others, through the communication interface. User interface 114 can include a Liquid Crystal Display (LCD), a Light Emitting Diode Display (LED), a plasma display, or any suitable graphical displays. User interface 114 can also include a Graphical User Interface (GUI) presented on the display for user input and data depiction. In some embodiments, information about waveform analysis results can be displayed on user interface 114. In some embodiments, an alert or a notification may be triggered and shown on user interface after one or more operations performed by waveform analyzing unit 112 are completed.

FIG. 1B illustrates an exemplary computer system 150 for implementing an exemplary waveform analyzing system such as waveform analyzing system 100, according to embodiments of the disclosure. Referring to FIG. 1B, computer system 150 can include at least one processor 155, a communication interface 160, and a memory 165. Memory 165 can be configured to store one or more computer instructions that, when executed by processor 155, can cause processor 155 to perform various operations disclosed herein. Memory 165 can be any non-transitory type of mass storage, such as volatile or non-volatile, magnetic, semiconductor-based, tape-based, optical, removable, non-removable, or other type of storage device or tangible computer-readable medium including, but not limited to, a ROM, a flash memory, a dynamic RAM, and a static RAM.

Processor 155 can be configured to perform the operations in accordance with the instructions stored in memory 165. Processor 155 can include any appropriate type of general-purpose or special-purpose microprocessor, digital signal processor, or microcontroller. Processor 155 can be configured as a separate processor module dedicated to performing one or more specific operations. Alternatively, processor 155 can be configured as a shared processor module for performing other operations unrelated to the one or more specific operations disclosed herein. Processor 155 can include various units or modules for performing waveform analysis. For example, processor 155 can include signal generators, waveform processing units, waveform analyzing units, circuit simulators, and/or any suitable modules for receiving and performing waveform analysis. For example, processor 155 can include processor modules dedicated to performing the operations conducted by waveform analyzing system 100, including control signal generator 102, circuit simulator 104, reference waveform processing unit 106, control signal analyzing unit 108, signal waveform processing unit 110, waveform analyzing unit 112, and any other suitable components of waveform analyzing system 100.

Communication interface 160 can include any type of communication adaptor, such as an integrated services digital network (ISDN) card, cable modem, satellite modem, or a modem to provide a data communication connection. As another example, communication interface 160 can include a local area network (LAN) card to provide a data communication connection to a compatible LAN. Wireless links can also be implemented by communication interface 160. In such an implementation, communication interface 160 can send and receive electrical, electromagnetic or optical signals that carry digital data streams representing various types of information via a network. The network can include a cellular communication network, a Wireless Local Area Network (WLAN), a Wide Area Network (WAN), or the like. In some embodiments, communication interface 160 can also include input/output interfaces, such as display interface (e.g., HDMI, DVI, VGA, etc.), audio interface, keyboard interface, mouse interface, printer interface, touch screen interface, etc.

Communication interface 160 can be configured to exchange information between computer system 150 and one or more other systems/devices. For example, communication interface 160 can communicate with a database 170, which can store information related to integrated circuit designs, device designs, routing rules, or the like. In some embodiments, database 170 can also store information related to waveform processing and analyzing, such as data processing algorithms, waveform analyzing algorithms, data processing recipes, threshold tolerance values, ratio values, sampling frequencies, or other suitable information related to the design and simulation of integrated circuits. In some embodiments, processor 155 can receive information stored in database 170 through communication interface 160.

A display 175 can be coupled to computer system 150 through communication interface 160. Display 175 can include an LCD, an LED, a plasma display, or any other type of display, and provide a GUI presented on the display for user input and data depiction. User interface 114 described above in FIG. 1A can include display 175. Display 175 can be formed of different types of materials, such as plastic or glass, and can be touch-sensitive to receive inputs from the user. For example, display 175 can include a touch-sensitive material that is substantially rigid or substantially pliable. In some embodiments, information about waveform analyzing results, timing data, and/or user input requests can be displayed on display 175. In some embodiments, an alert may be triggered and shown on display 175 after one or more operations performed by processor 155 are completed.

A terminal device 180 can be coupled to computer system 150 through communication interface 160. Terminal device 180 can include a desktop computer, a workstation, a laptop computer, a mobile phone, a tablet, or any other type of device configured to perform computational tasks. In some embodiments, a user can use terminal device 180 to control computer system 150, for example, to initiate, monitor, or terminate operations related to reviewing and analyzing waveforms. In some embodiments, terminal device 180 can receive information about waveform analysis generated by computer system 150. In some embodiments, terminal device 180 can receive notification or alerts indicating the status of operations performed by processor 155. For example, a signal indicating a waveform passing a threshold value test process can be communicated to terminal device 180 through communication interface 160. In another example, a signal indicating a waveform failing the threshold value test process can be communicated to terminal device 180, and terminal device 180 can initiate remedy measures for feeding back to the circuit design process, such as changing one or more circuit parameters or circuit element values. In some embodiments, the circuit parameters can include, but not limited to, circuit element values, routings options, timing values, and the like. Circuit element values can includes, but not limited to, resistances, capacitances, inductances, routings, timing values, and the like.

One or more of database 170, display 175, and/or terminal device 180 can be part of computer system 150, and can be co-located with computer system 150 or located remotely with respect to computer system 150 and communicate with computer system 150 via a network or any suitable type of communicate link.

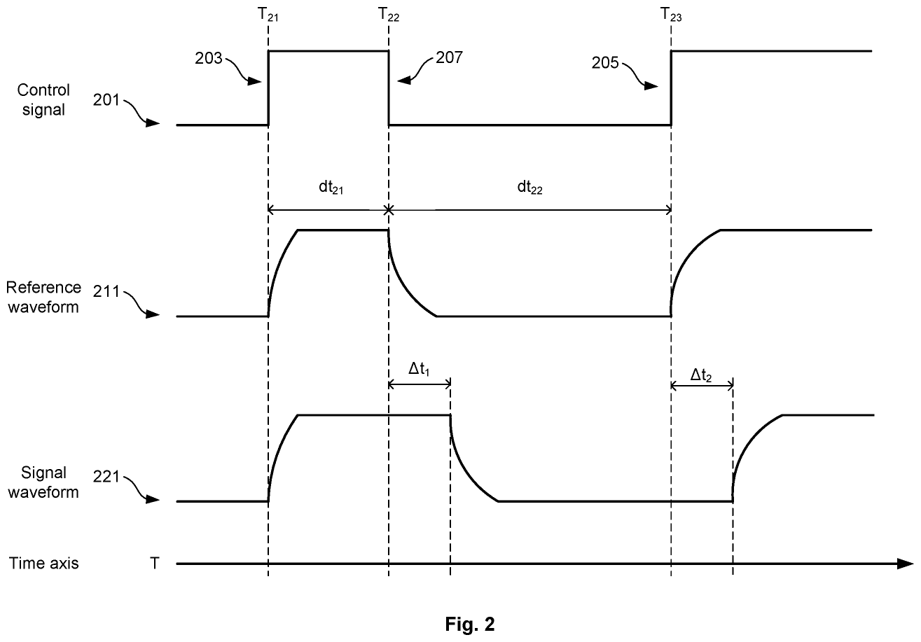

FIG. 2 is a schematic diagram illustrating a control signal and exemplary signal waveforms, in accordance with some embodiments. FIG. 2 illustrates a control signal 201, a reference waveform 211, and a signal waveform 221. A time axis T is also illustrated. Control signal 201 illustrated in FIG. 2 includes rising edges 203 and 205 occurring at time values T21 and T23, respectively. Control signal 201 also includes falling edge 207 occurring at time value T22. Referring to FIG. 1A, waveform analyzing unit 112 is configured to identify the rising and falling edges of control signal 201 and determine T21, T22, and T23 as characteristic points. The adjacent pairs of characteristic points divide the time axis into various time durations. For example, characteristic points T21 and T22 abut time duration dt21, whereas characteristic points T22 and T23 abut time duration dt22. As shown in reference waveform 211, rising edges 203 and 205 as well as falling edge 207 trigger a response in reference waveform 211. In some embodiments, reference waveform 211 illustrated in FIG. 2 is an ideal waveform and displays no delay in response to characteristic points of control signal 201. In contrast, signal waveform 221 displays delays in response to characteristic points T22 and T23 of control signal 201. For example, signal response of signal waveform 221 is delayed by delay times Δt1 and Δt2 in response to characteristic points T22 and T23, respectively. In some embodiments, the signal response demonstrated by signal waveform 221 can be acceptable despite the delays. However, a waveform comparison method using a pattern comparison technique may falsely report that signal waveform 221 is unacceptable due to the shift in wave shapes.

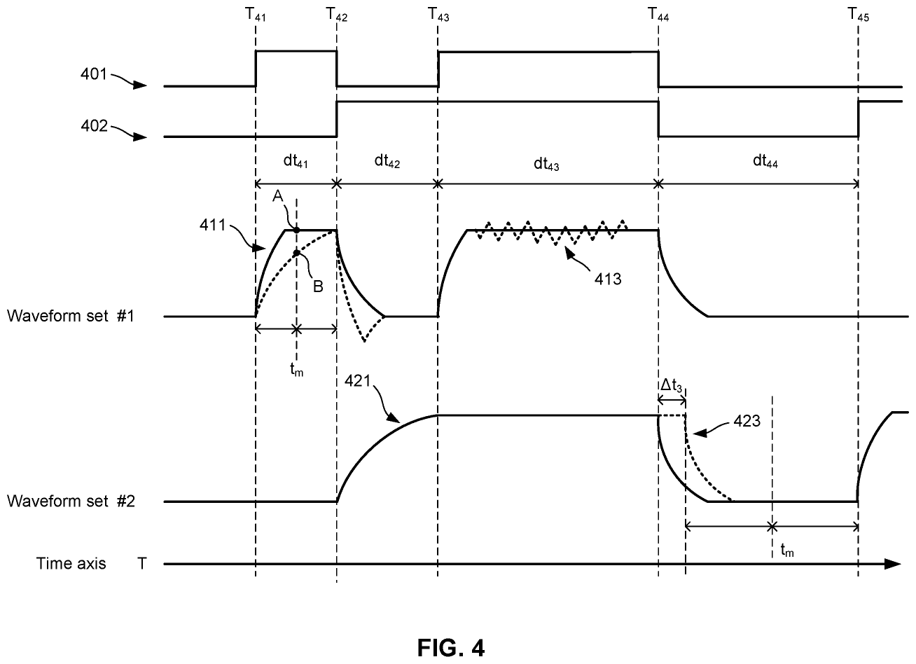

FIG. 3 is a flow diagram of an exemplary method 300 for analyzing waveforms using a waveform analyzing system, in accordance with some embodiments of the present disclosure. The operations of method 300 can be performed in a different order and/or vary, and method 300 can include more operations that are not described for simplicity. Any reasonable application of method 300 in circuit simulation is within the scope of this disclosure. For illustrative purposes, the operations illustrated in FIG. 3 will be described with reference to the waveform analyzing system, computer system, and waveforms illustrated in FIGS. 1A, 1B, and 4, respectively.

In operation 310, characteristic points of a control signal is determined, according to some embodiments. Referring to FIG. 4, control signals 401 and 402 are supplied to suitable components of an integrated circuit. In some embodiments, control signal generator 102 illustrated in FIG. 1A is configured to generate control signals 401 and 402 and send the control signals to at least circuit simulator 104, reference waveform processing unit 106, control signal analyzing unit 108, and signal waveform processing unit 110. Control signal analyzing unit 108 can be configured to detect rising and falling edges and further determine characteristic points such as T41-T45 using methods described above with regard to FIG. 1A. Time durations are periods of time abutting adjacent characteristic points. For example, time duration dt41 abuts characteristic points T41 and T42.

In operation 320, data sampling frequencies for time durations are determined, in accordance with some embodiments of the present disclosure. Referring to FIG. 1A, waveform analyzing unit 112 can be configured to store pre-determined sampling frequencies in its internal storage (not illustrated in FIG. 1A for simplicity). In some embodiments, waveform analyzing unit 112 can be configured to receive the sampling frequencies via user interface 114. Data sampling frequency can be set to different frequencies for different time durations, depending on the analysis method used for the corresponding time duration. For example, referring to FIG. 4, a sampling frequency for time duration dt41 can be different from a sampling frequency for time duration dt43. In some embodiments, data sampling frequency can be dependent upon a time duration between adjacent characteristic points. For example, a data sampling frequency can be dependent upon a frequency of a control signal. In some embodiments data sampling frequency can be dependent upon differences in time values of adjacent characteristic points. In response to the difference in time values being greater than a threshold time value, waveform analyzing unit 112 is configured to increase the amount of data sampling points by increasing data sampling frequency. In response to the difference in time values being less than a threshold time value, waveform analyzing unit 112 is configured to decrease the amount of data sampling points by decreasing data sampling frequency. In some embodiments, a single data point is obtained from a mid-point (i.e., middle time point) within time duration dt41 and a group of data points (e.g., between about 5 and 200) are obtained within time duration dt43 to obtain an average data value.

In operation 330, data values of signal waveforms and reference waveforms within selected time durations are determined, in according with some embodiments of the present disclosure. Referring to FIG. 1A, waveform analyzing unit 112 can send instructions to reference waveform processing unit 106 and signal waveform processing unit 110 to obtain data values of one or more reference waveforms and one or more signal waveforms within selected time durations, as explained below.

Referring to FIG. 4, waveform set #1 includes a reference waveform 411 (represented by a solid line) and a signal waveform 413 (represented by a dotted line). Similarly, waveform set #2 includes a reference waveform 421 (represented by a solid line) and a signal waveform 423 (represented by a dotted line). Waveform sets #1 and #2 are controlled by control signals 401 and 402, respectively. In some time durations, reference waveforms and signal waveforms substantially overlap. For example, reference waveform 411 and signal waveform 413 substantially overlap in time duration dt44, and the waveforms are not separately labelled for simplicity.

Reference waveform processing unit 106 and signal waveform processing unit 110 can be configured to obtain data values within a specific time duration using one or more analysis methods. In some embodiments, the analysis methods can be different for different time durations. In some embodiments, the analyzing process can be performed multiple times using different analysis methods. For example, an initial analyzing process on a set of waveforms can be performed using an average value method and a subsequent analyzing process on the same set of waveforms can be performed using a peak analysis method. The initial analyzing process can serve as an initial filter to detect errors in waveforms and the subsequent analyzing process can be used to confirm or eliminate the errors. In some embodiments, the initial analyzing process and subsequent analyzing process can use any combination of suitable analysis methods, such as mid-point analysis method, peak analysis method, and average value analysis method. In some embodiments, the analysis method can be applied similarly within a signal waveform but different between different waveforms.

In some embodiments, an analysis method can be a mid-point analysis method. For example, a data value is obtained at a time that is at a middle of a time duration. Referring to waveform set #1 within time duration dt41 of FIG. 4, data values A and B are obtained at middle time point tm for reference waveform 411 and signal waveform 413, respectively. In another example, mid-point analysis can be used in time duration dt44 for waveform set #2. As shown in FIG. 4, although signal waveform 423 displays a time delay of Δt3 with respect to reference waveform 421, data values obtained for both waveforms using mid-point analysis are substantially the same.

In some embodiments, an analysis method can be a peak analysis method. For example, a peak analysis method can include obtaining maximum amplitudes of the data values for reference waveform 411 and signal waveform 413 within a time duration. Any suitable peak analysis method can be used. For example, a difference between a positive peak and an adjacent negative peak can be determined. In some embodiments, a time difference between adjacent positive peaks can be determined. As an example, a peak analysis method can be applied to reference waveform 411 and signal waveform 413 within time duration dt42 of FIG. 4.

In some embodiments, an analysis method can be an average value method. For example, a group of data values can be obtained within a time duration and an average value of the group of data values is calculated using the group of data values. In some embodiments, a group of data values can be obtained for reference waveform 411 and signal waveform 413 within time duration dt43. For example, reference waveform processing unit 106 and signal waveform processing unit 110 can be configured to calculate an average data value within time duration dt43 for the respective waveforms.

In some embodiments, an analysis method can include obtaining data values at specific time values. For example, data values can be obtained at a suitable time interval, such as every 5 μs or 10 μs, for example, depending on the frequency of the control signals. In some embodiments, data values at any other suitable time values can be obtained.

In operation 340, differences between data values of the signal waveform and the reference waveform are determined using one or more analysis methods, in accordance with some embodiments of the present disclosure. Referring to FIG. 1A, waveform analyzing unit 112 can be configured to determine differences between data values obtained from operation 330. Specifically, waveform analyzing unit 112 can calculate value differences of reference waveforms and signal waveforms within a specific time duration. For example, referring to FIG. 4, waveform analyzing unit 112 can be configured to calculate differences between mid-point data values A and B within time duration dt41, differences between peak-to-peak values within time duration dt42, and/or average data values within time duration dt43. In some embodiments, any other suitable differences in data values can be calculated and are not described in detail herein for simplicity.

In operation 350, waveform analyzing system is configured to determine whether the signal waveform is an acceptable waveform and output a notification to a user interface, in accordance with some embodiments of the present disclosure. Referring to FIG. 1A, waveform analyzing unit 112 is configured to determine if the differences in data values, such as data values obtained in operation 340, are within a pre-determined threshold tolerance value. In some embodiments, the threshold tolerance value can be stored in waveform analyzing unit 112. In some embodiments, the threshold tolerance value can be provided by a user via user interface 114. In some embodiments, examples of threshold tolerance value can be a voltage level, a time value, a frequency value, any suitable values for analyzing a waveform, and/or combinations thereof. If the differences between data values of a signal waveform and a reference waveform is within a threshold tolerance value, waveform analyzing unit 112 can be configured to record an acceptable signal. Alternatively, if the differences between data values of a signal waveform and a reference waveform is greater than a threshold tolerance value, waveform analyzing unit 112 can be configured to record an error signal. Waveform analyzing unit 112 can further be configured to adjust at least one circuit parameter of the integrated circuit based on the differences. In some embodiments, the circuit parameters can include, but not limited to, circuit element values, routings options, timing values, and the like. Circuit element values can includes, but not limited to, resistances, capacitances, inductances, routings, timing values, and the like. For example, in response to a difference between time delays for signal and reference waveforms being greater than a threshold value, waveform analyzing unit 112 can be configured to adjust resistance and/or capacitance of one or more circuit elements such that RC time constant is adjusted. Waveform analyzing unit 112 can also be configured to automatically perform waveform analysis after the adjustment, using methods similar to those described in operations 310-350 until the difference between signal and reference waveforms are below the threshold tolerance value. Waveform analyzing unit 112 can perform such analysis for a portion of or an entire signal waveform and determine a ratio of a number of acceptable signals over a number of error signals. Waveform analyzing unit 112 can be configured to compare the determined ratio with a stored threshold ratio to determine if the signal waveform is acceptable. In response to the ratio being less than a threshold ratio value, waveform analyzing unit 112 can be configured to output an alert signal to user interface 114. In response to the ratio being greater than a threshold ratio value, waveform analyzing unit 112 can be configured to output a notification to user interface 114 indicating that the signal waveform is acceptable.

Various embodiments in the present disclosure describe methods and system for analyzing signal waveforms in an integrated circuit. A waveform analyzing system can be configured to receive signal waveforms and analyze the received signal waveforms with respect to one or more reference waveforms. The methods described in the present disclosure includes determining characteristic points of a control signal and determining data sampling frequency of the signal waveform based on the characteristic points. The data sampling frequency can be different between different time durations between adjacent characteristic points. The waveform analyzing system can be configured to measure the sampled signal data from different time durations using different methods. In some embodiments, the waveform analyzing system is configured to receive multiple signal waveforms and use different analysis methods to determine if one or more signal waveforms meet a predetermined criteria.

The foregoing disclosure outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method for analyzing signal waveforms produced by an integrated circuit, comprising:
determining a plurality of characteristic points of a control signal, wherein each characteristic point comprises a corresponding time value and represents an edge change of the control signal;
determining a plurality of sets of data sampling points, wherein each set of data sampling points is located between adjacent characteristic points of the plurality of characteristic points;
obtaining a plurality of data values of a signal waveform, wherein a data value of the signal waveform is obtained at a data sampling point of the plurality of sets of data sampling points;
obtaining a plurality of data values of a reference waveform, wherein a data value of the reference waveform is obtained at the data sampling point; and
comparing the data value of the signal waveform to the data value of the reference waveform.

2. The method of claim 1, wherein comparing the data value of the signal waveform to the data value of the reference waveform comprises:
determining a difference between the data value of the signal waveform and the data value of the reference waveform; and
comparing the difference with a threshold tolerance value.

3. The method of claim 2, wherein:
in response to the difference being greater than the threshold tolerance value, the method further comprises recording an error signal; and
in response to the difference being less than the threshold tolerance value, the method further comprises recording an acceptable signal.

4. The method of claim 3, further comprising determining a plurality of differences between the plurality of data values of the signal waveform and the plurality of data values of the reference waveform and obtaining a plurality of error signals and a plurality of acceptable signals.

5. The method of claim 4, further comprising determining a ratio of a number of the plurality of acceptable signals over a number of the plurality of error signals.

6. The method of claim 5, wherein in response to the ratio being less than a threshold ratio value, the method further comprises outputting an alert signal.

7. The method of claim 1, further comprising arranging the plurality of characteristic points in an ascending order based on the time value of each of the characteristic points.

8. The method of claim 1, further comprising adjusting an amount of data sampling points within a set of data sampling points based on a difference in time values of the adjacent characteristic points.

9. The method of claim 8, wherein, in response to the difference in time values being greater than a threshold time value, the method further comprises increasing the amount of data sampling points.

10. The method of claim 8, wherein, in response to the difference in time values being less than a threshold time value, the method further comprises reducing the amount of data sampling points.

11. The method of claim 2, wherein determining the difference between the data value of the signal waveform and the data value of the reference waveform comprises determining a difference between respective peak-to-peak values of the signal waveform and the reference waveform.

12. A method for analyzing signal waveforms produced by an integrated circuit, comprising:
determining a plurality of characteristic points of a control signal, wherein each characteristic point comprises a corresponding time value and represents an edge change of the control signal;
determining a plurality of time durations, wherein each time duration is between adjacent time values of respective adjacent characteristic points of the plurality of characteristic points;
obtaining a first plurality of data values of a signal waveform in a first time duration of the plurality of time durations;
obtaining a first plurality of data values of a reference waveform in the first time duration;
determining, using a first analysis method, a first difference between the first plurality of data values of the signal waveform and the first plurality of data values of the reference waveform;
obtaining a second plurality of data values of the signal waveform in a second time duration of the plurality of time durations;
obtaining a second plurality of data values of the reference waveform in the second time duration;
determining, using a second analysis method different from the first analysis method, a second difference between the second plurality of data values of the signal waveform and the second plurality of data values of the reference waveform; and
comparing the first or second difference with a threshold tolerance value.

13. The method of claim 12, further comprising:
in response to the first or second difference being greater than the threshold tolerance value, adjusting at least one circuit parameter of the integrated circuit.

14. The method of claim 12, wherein the first and second analysis methods comprise a peak analysis method and an average value analysis method, respectively.

15. The method of claim 14, wherein the peak analysis method comprises comparing a maximum amplitude of the first plurality of data values of the signal waveform and a maximum amplitude of the first plurality of data values of the reference waveform.

16. The method of claim 14, wherein the average value analysis method comprises comparing an average value of the second plurality of data values of the signal waveform and an average value of the second plurality of data values of the reference waveform.

17. The method of claim 12, wherein the first analysis method comprises comparing a first data value of the signal waveform obtained at a mid-point of the first time duration and a first data value of the reference waveform obtained at the mid-point.

18. The method of claim 12, wherein the first and second analysis methods comprise a mid-point analysis method and a peak analysis method, respectively.

19. The method of claim 12, wherein the first and second analysis methods comprise a mid-point analysis method and an average value analysis method, respectively.

20. A non-transitory computer-readable medium containing computer-executable program for, when being executed by a processor, implementing a method for analyzing signal waveforms produced by an integrated circuit, comprising:
determining a plurality of characteristic points of a control signal, wherein each characteristic point comprises a corresponding time value and represents an edge change of the control signal;
determining a plurality of sets of data sampling points, wherein each set of data sampling points is located between adjacent characteristic points of the plurality of characteristic points;
obtaining a plurality of data values of a signal waveform, wherein a data value of the signal waveform is obtained at a data sampling point of the plurality of sets of data sampling points;
obtaining a plurality of data values of a reference waveform, wherein a data value of the reference waveform is obtained at the data sampling point; and
comparing the data value of the signal waveform to the data value of the reference waveform.
